(19) United States
(12) Patent Application Publication
(10) Pub. No.: US 2026/0282807 A1
(43) Pub. Date: Sep. 17, 2026

(54) PRESS DIE DEVICE, UPPER DIE FIXTURE HAVING THE SAME, AND PRESS APPARATUS

(71) Applicant: ALL RING TECH CO., LTD., Kaohsiung City (TW)

(72) Inventors: Tai-Hung LIU, Kaohsiung City (TW); Chien-Min LIU, Kaohsiung City (TW)

(21) Appl. No.: 19/381,969

(22) Filed: Nov. 6, 2025

(30) Foreign Application Priority Data
Mar. 17, 2025 (TW) 114109826

(51) Int. Cl. H01L 21/67

(52) U.S. Cl. CPC H10P 72/0438

(57) ABSTRACT

A press die device includes a connecting assembly and a press assembly. The connecting assembly includes an axial rod, a bushing sleeved on the axial rod, and at least one key connection structure connecting the axial rod and the bushing. The press assembly is mounted to a bottom end of the axial rod, and includes a press die adapted to press a to-be-pressed object.

### CROSS-REFERENCE TO RELATED APPLICATION

This application claims priority to Taiwanese Invention Patent Application No. 114109826, filed on Mar. 17, 2025, the entire disclosure of which is incorporated by reference herein.

### FIELD

The disclosure relates to packaging of an integrated circuit component, and more particularly to a press die device, an upper die fixture having the press die device and a press apparatus for packaging the integrated circuit component.

### BACKGROUND

A conventional press apparatus for packaging an integrated circuit component includes a lower die fixture on which a plurality of to-be-pressed objects are arranged in a matrix, and an upper die fixture movable up and down and cooperating with the lower die fixture to press the to-be-pressed objects. Each of the to-be-pressed objects has a rectangular cross-section, and includes, from bottom to top, a substrate, a chip, a thermal interface material, and a heat sink. The upper die fixture includes a plurality of pressing units that are the same in number with the to-be-pressed objects. Generally, the pressing units respectively press the to-be-pressed objects vertically and downwardly to achieve a relatively good pressing quality, ensuring a relatively good packaging quality in subsequent processes. Each of the pressing units is, for example, a pressing unit disclosed in Taiwanese Invention Patent No. I804790.

The pressing unit disclosed in Taiwanese Invention Patent No. I804790 includes a pressing rod and a positioning unit for maintaining stability of the pressing rod in an up-down direction and radial directions perpendicular to the up-down direction when the pressing units respectively press the to-be-pressed objects. However, the positioning unit has a relatively complex structure and may increase cost for manufacturing the pressing unit.

### SUMMARY

Therefore, an object of the present disclosure is to provide a press die device, an upper die fixture, and a press apparatus that can alleviate at least one of the drawbacks of the prior art.

According to an aspect of the disclosure, a press die device includes a connecting assembly and a press assembly. The connecting assembly includes an axial rod, a bushing sleeved on the axial rod, and at least one key connection structure connecting the axial rod and the bushing. The press assembly is mounted to a bottom end of the axial rod, and includes a press die adapted to press a to-be-pressed object.

According to another aspect of the disclosure, an upper die fixture includes at least one press die device as described above, and an upper die seat. The upper die seat includes at least one mounting area, a number of the at least one mounting area being the same as a number of the at least one press die device. The at least one press die device is mounted to the at least one mounting area. The at least one press die device is connected to the at least one mounting area by the bushing. The axial rod is movable in an axial direction of the axial rod and drives the press assembly to move relative to the upper die seat in the axial direction.

According to still another aspect of the disclosure, a press apparatus includes the upper die fixture as described above, and a lower die fixture cooperating with the at least one press die device of the upper die fixture to press at least one to-be-pressed object.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view of a press die device of an upper die fixture of a press apparatus of an embodiment according to the present disclosure.

FIG. 2 is an exploded perspective view of the press die device.

FIG. 3 is a sectional view taken along line III-III in FIG. 1, illustrating structures of the press die device of the embodiment.

FIG. 4 is a sectional view taken along line IV-IV in FIG. 1, illustrating structures of the press die device.

FIG. 5 is a sectional view taken along line V-V in FIG. 3, illustrating a connecting assembly of the press die device.

FIG. 6 is an exploded sectional view illustrating the connecting assembly of the press die device.

FIG. 7 is a cross-sectional view similar to FIG. 5, but illustrating a modification of a key connection structure of the connecting assembly of the embodiment.

FIG. 8 is a cross-sectional view similar to FIG. 5, but illustrating another modification of the key connection structure of the connecting assembly of the embodiment.

FIG. 9 is a perspective view of the press apparatus of the embodiment.

FIG. 10 is a front view of the press apparatus of the embodiment.

FIG. 11 is a partly exploded perspective view of the upper die fixture of the press apparatus of the embodiment.

FIG. 12 is a partly exploded perspective view of the upper die fixture of the embodiment.

FIG. 13 is a fragmentary top view of the upper die fixture.

FIG. 14 is a fragmentary perspective view of a lead frame of the upper die fixture.

FIG. 15 is a sectional view illustrating a fixture driving member of the press apparatus of the embodiment driving downward movement of the upper die fixture so one of the press die devices presses a to-be-pressed object.

FIG. 16 is a sectional view illustrating a press die driver member of the press apparatus driving one of the press die devices to press the to-be-pressed object.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

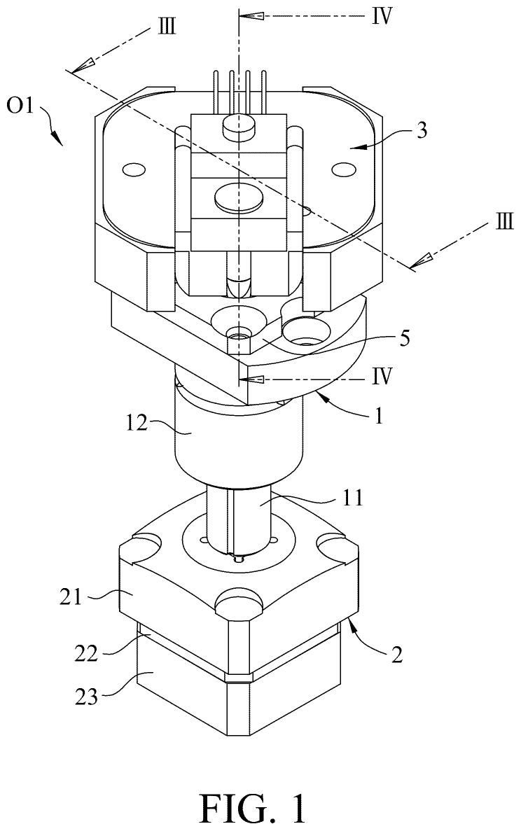

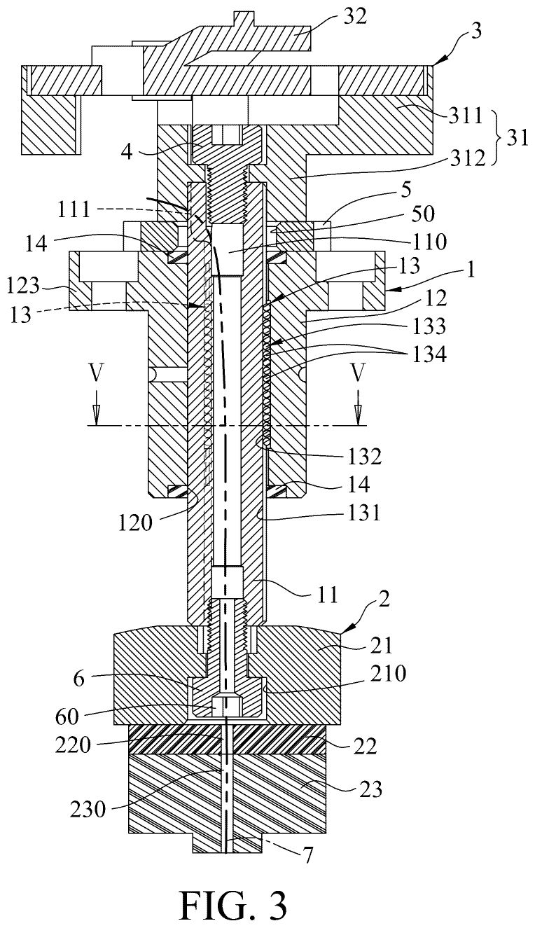

Referring to FIGS. 1 to 3 and 9, a press apparatus (O3) of one embodiment according to the present disclosure includes an upper die fixture (O2) that includes a plurality of press die devices (O1). Since the structures of the press die devices (O1) are identical, only one of the press die devices (O1) (see FIG. 1) will be described in the following for the sake of brevity. The press die device (O1) includes a connecting assembly 1, a press assembly 2 mounted to a bottom portion of the connecting assembly 1, a pressure detection mechanism 3 mounted on an upper end of the connecting assembly 1, an upper fastener 4 fixedly connecting the connecting assembly 1 and the pressure detection mechanism 3, a spacer 5 disposed between the connecting assembly 1 and the pressure detection mechanism 3, a lower fastener 6 (see FIG. 3) fixedly connecting the connecting assembly 1 and the press assembly 2, and a temperature sensor 7 extending through the connecting assembly 1 and the press assembly 2 to a bottom end of the press assembly 2.

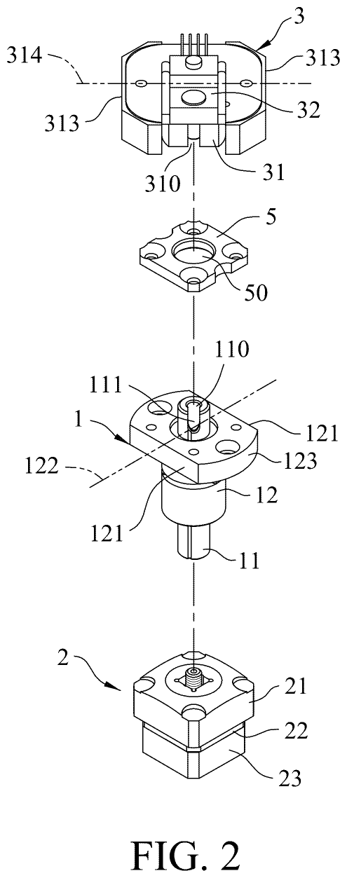

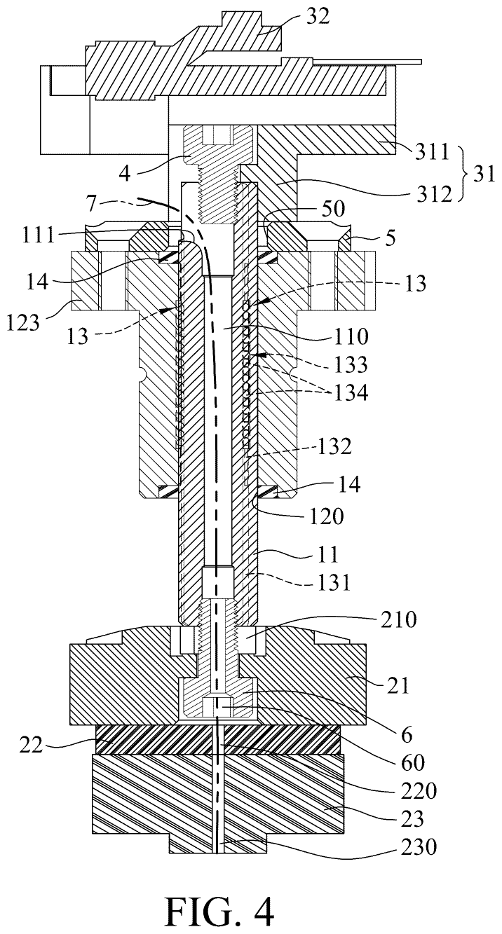

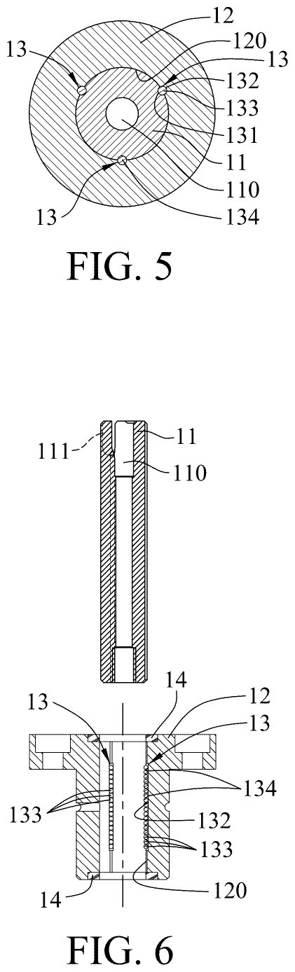

Referring to FIGS. 3 to 6, the connecting assembly 1 includes an axial rod 11 extending in an axial direction, a bushing 12 sleeved on the axial rod 11, three key connection structures 13 equiangularly disposed between the axial rod 11 and the bushing 12, and two sealing rings 14 respectively mounted to top and bottom sides of the bushing 12 adjacent to the axial rod 11 in the axial direction. The axial rod 11 is formed with an axial hole 110 extending in the axial direction and an upper portion of the axial rod 11 is formed with a slot 111 (see FIG. 2) that is in spatial communication with the axial hole 110. It should be noted that in this embodiment, the axial direction is an up-down direction in FIGS. 1 to 4 and the axial rod 11 is movable in the axial direction relative to the bushing 12. The bushing 12 is formed with a bushing hole 120 for extension of the axial rod 11 therethrough. The key connection structures 13 connect the axial rod 11 and the bushing 12. Each of the key connection structures 13 includes a key slot 131 formed in an outer peripheral surface of the axial rod 11 and extending in the axial direction, a connection seat 132 formed on an inner peripheral surface of the bushing 12 that defines the bushing hole 120 and corresponding in position to the key slot 131, and a plurality of key members 133 interconnecting the key slot 131 and the connection seat 132. In this embodiment, for each of the key connection structures 13, the key members 133 are linearly arranged between the key slot 131 and the connection seat 132 and are a plurality of balls 134 freely rotatable in multiple directions.

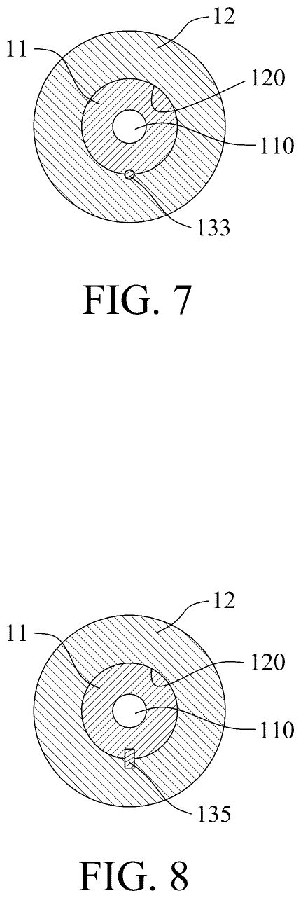

In some modifications of the embodiment, the number of the key connection structures 13 is not limited to three and may be one, two, four or more. For example, as shown in FIGS. 7 and 8, there may be only one key connection structure 13. Additionally, the more the number of the key connection structures 13, the smaller an interval angle between any two adjacent ones of the key connection structures 13. In this embodiment, the key connection structures 13 are equiangularly disposed between the axial rod 11 and the bushing 12, i.e., arranged at equal intervals, to increase connection stability therebetween and thus reduce shaking of the axial rod 11. Referring to FIG. 8, in a case where the number of key members 133 is one, the key member 133 is, for example, but not limited to, a key block 135 that has a rectangular cross-section.

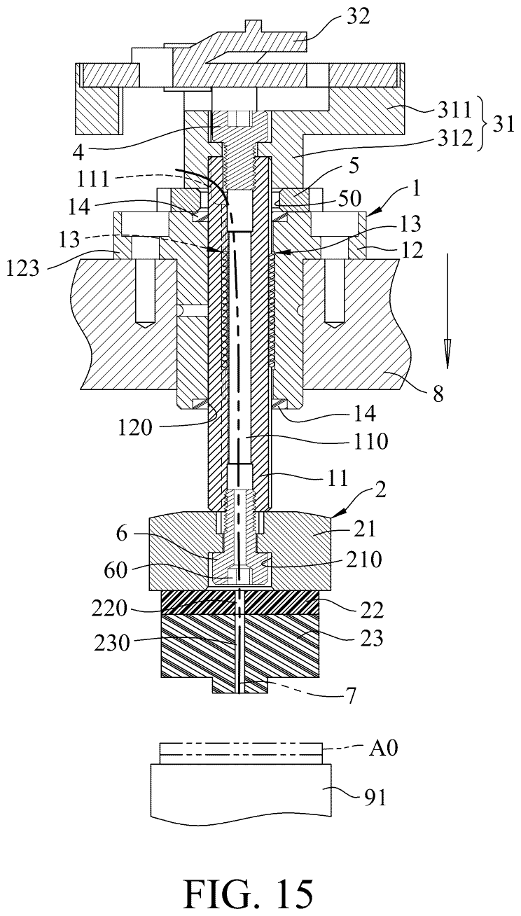

Referring back to FIGS. 2 to 4, the press assembly 2 is detachably mounted to a bottom end of the axial rod 11, and includes a press seat 21 detachably connected to a bottom portion of the axial hole 110 by the lower fastener 6, a heat insulation element 22 mounted to the press seat 21, and a press die 23 mounted to the heat insulation element 22, and operable to press a to-be-pressed object (A0) (see FIG. 15). The press seat 21 is formed with a lower fastening hole 210 for extension of the lower fastener 6 therethrough. In this embodiment, the press die 23 is made of non-metal material and is pressure-resistant and temperature-resistant. The to-be-pressed object (A0) is, e.g., an integrated circuit component obtained after placement of a heat sink in a semiconductor manufacturing process, and includes, from bottom to top, a substrate, a chip, a thermal interface material, and a heat sink, but the to-be-pressed object (A0) is not limited to this example. In one embodiment, the press seat 21, the heat insulation element 22, and the press die 23 are assembled together with screws.

The pressure detection mechanism 3 is mounted to the axial rod 11, and includes a support table 31 connected to the upper portion of the axial rod 11, and a pressure sensor 32 mounted to an upper portion of the support table 31. The support table 31 has a support portion 311 on which the pressure sensor 32 is mounted, and a mount portion 312 sleeved on the axial rod 11. A width of the support portion 311 in a left-right direction shown in FIG. 3 transverse to the axial direction is greater than a width of the mount portion 312 in the left-right direction. The upper fastener 4 extends into and fixedly connects the support table 31 and an upper portion of the axial hole 110.

It should be noted that, as shown in FIG. 2, the support table 31 has two first side edges 313 transverse to the axial direction, parallel to each other, and perpendicular to a first line 314. The bushing 12 has two second side edges 121 transverse to the axial direction, parallel to each other, and perpendicular to a second line 122. A projection of the first line 314 in the axial direction on a horizontal plane that is normal to the axial direction is not parallel to a projection of the second line 122 in the axial direction on the horizontal plane. In this embodiment, projections of the first line 314 and the second line 122 on the horizontal plane intersect at 45 degrees.

The spacer 5 is disposed between the support table 31 and the bushing 12 in the axial direction, and is formed with an opening 50 for extension of the axial rod 11 therethrough. The lower fastener 6 is formed with a first channel 60 in spatial communication with the axial hole 110. The heat insulation element 22 is mounted to a bottom end of the press seat 21, and is formed with a second channel 220 in spatial communication with the first channel 60. The press die 23 is connected to a bottom end of the heat insulation element 22 and is formed with a third channel 230 in spatial communication with the second channel 220. In this embodiment, the bushing hole 120, the axial hole 110, the first channel 60, the second channel 220, and the third channel 230 extend coaxially. The temperature sensor 7 is configured as a wire, is inserted from an exterior of the axial rod 11 through the slot 111 and extends sequentially through the axial hole 110, the first channel 60, the second channel 220, and the third channel 230 into a bottom end of the press die 23.

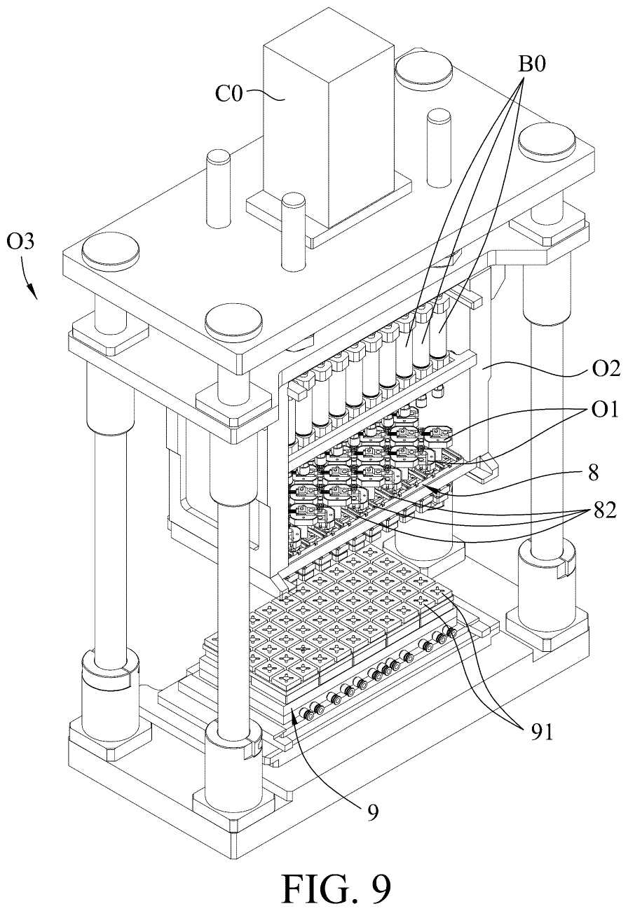

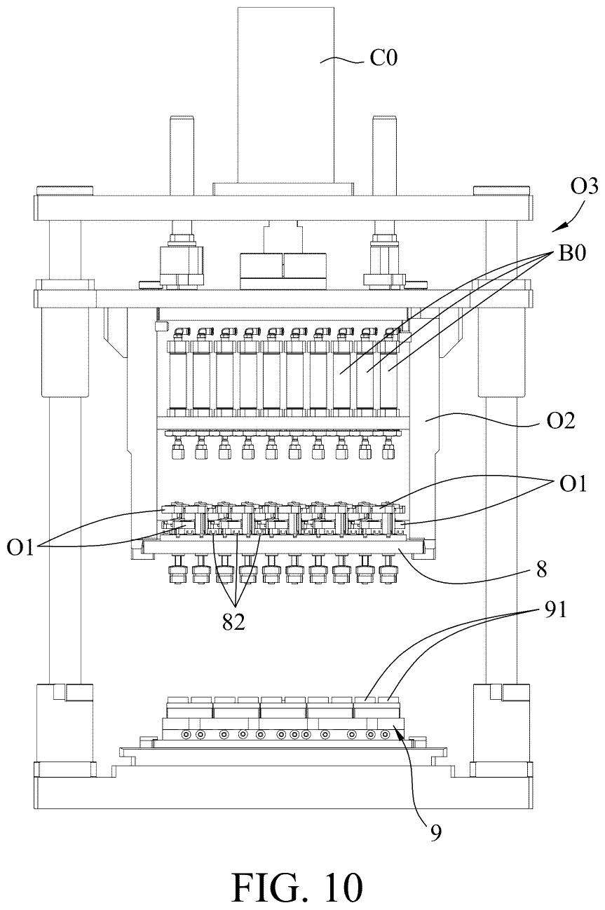

Referring to FIGS. 9 to 12, the upper die fixture (O2) includes fifty of the press die devices (O1) described above, an upper die seat 8 for mounting of the press die devices (O1), and fifty driving components (B0) respectively located above the press die devices (O1) and respectively driving movement of the press die devices (O1) in the axial direction. The driving components (B0) are, for example, but not limited to, pneumatic cylinder driving components.

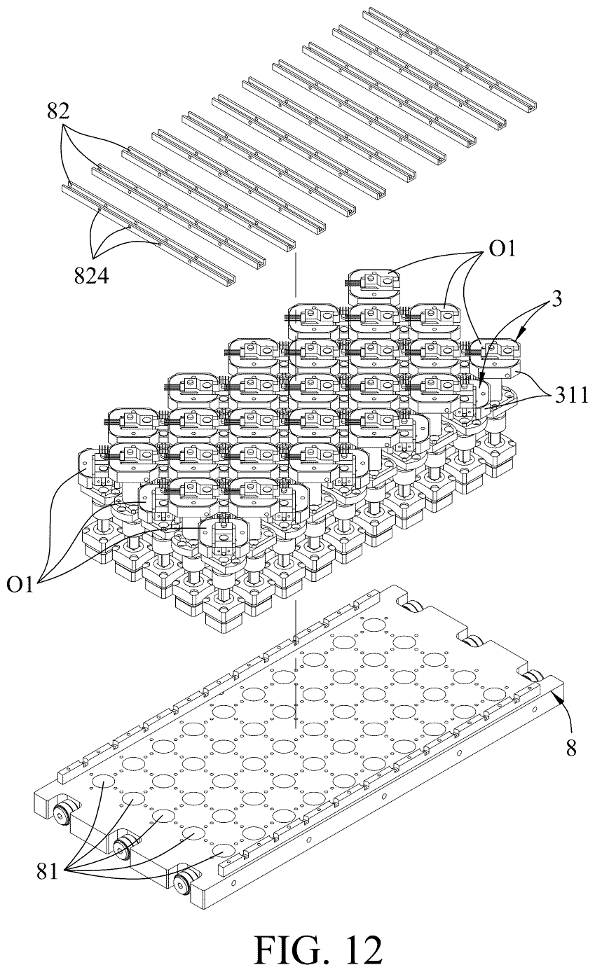

As shown in FIG. 12, the upper die seat 8 includes a plurality of mounting areas 81 and a plurality of lead frames 82. The number of the mounting areas 81 is the same as the number of the press die devices (O1) and is fifty in this embodiment. The press die devices (O1) are respectively mounted to the mounting areas 81. The number of the lead frames 82 is eleven, and every two adjacent ones of the lead frames 82 flank five of the mounting areas 81 that are arranged in a row. That is to say, every five of the mounting areas 81 are arranged in a row between two adjacent ones of the lead frames 82. In this embodiment, each of the mounting areas 81 is a through hole extending through the upper die seat 8.

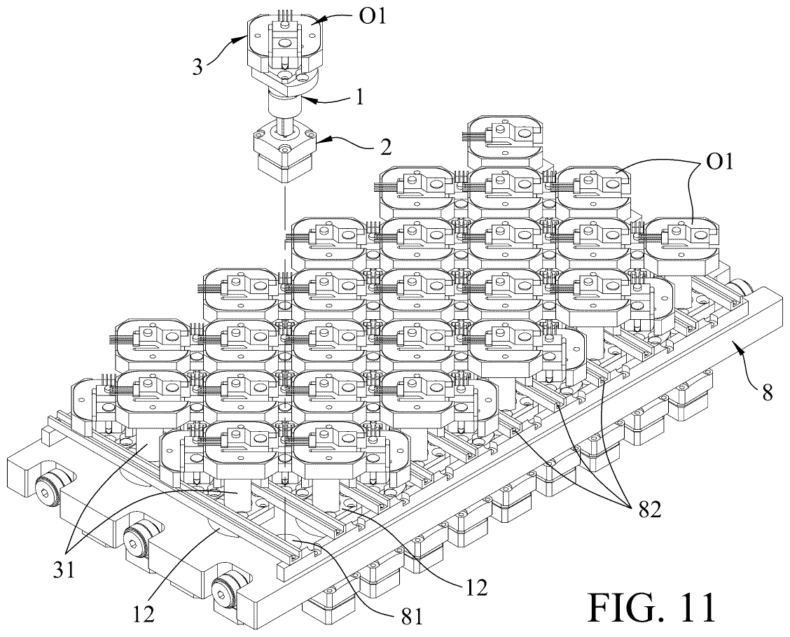

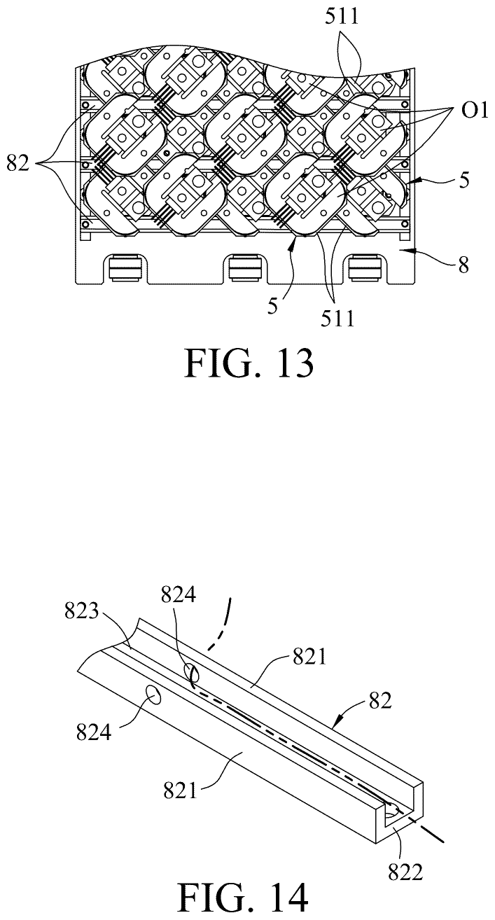

Every five of the press die devices (O1) are arranged in a row between two adjacent ones of the lead frames 82. Each of the press die devices (O1) is connected to the respective one of the mounting areas 81 by the bushing 12 thereof, and is disposed between two adjacent ones of the lead frames 82. It should be noted that two adjacent ones of the press die devices (O1) arranged in a row are located at difference heights in the axial direction, and any two adjacent ones of the press die devices (O1) are arranged staggered in the axial direction. In this way, the press die devices (O1) may be densely arranged on the upper die seat 8 in a staggered manner and occupy a relatively small space to minimize an overall size of the upper die seat 8 and the press die devices (O1). As shown in FIGS. 11 to 13, the support portions 311 of the support tables 31 of the pressure detection mechanisms 3 of two adjacent ones of the press die devices (O1) overlap with each other.

Referring to FIGS. 2, 11, 12 and 15, in this embodiment, a procedure of mounting one of the press die devices (O1) to the upper die seat 8 is described below. Since the structures of the press die devices (O1) are identical and the structures of the mounting areas 81 are identical, only one of the press die devices (O1) and the respective one of the mounting areas 81 will be described in the following for the sake of brevity. First, the axial rod 11 and a lower portion of the bushing 12 of the connecting assembly 1 of the press die device (O1) are inserted into the mounting area 81, and the bushing 12 has an upper flange 123 abutting against an upper side of the upper die seat 8 such that the bushing 12 is fixedly connected to the mounting area 81. As such, the upper portion of the axial rod 11 is exposed from the upper side of the upper die seat 8, and a lower portion of the axial rod 11 is exposed from a bottom side of the upper die seat 8. Subsequently, the press assembly 2 of the press die device (O1) is fixedly connected to the axial rod 11 by the lower fastener 6 that extends into the press assembly 2 and the axial rod 11. In this way, the axial rod 11 may drive the press assembly 2 to move therewith in the axial direction. After the connecting assembly 1 and the press assembly 2 are assembled together, the lead frames 82 are mounted on two spaced-apart racks flanking the ten rows of the mounting areas 81. Finally, the spacer 5 and the pressure detection mechanism 3 are sequentially sleeved on the axial rod 11 to be disposed on the bushing 12 and located above the upper die seat 8.

It should be noted herein that, in other embodiments, the procedure of mounting the press die device (O1) to the upper die seat 8 is not limited to the above description, and may be modified according to actual requirements. For example, the structures and sizes of the mounting area 81, the bushing 12 and the press assembly 2 may be modified and the procedure for mounting the press die device (O1) may be modified accordingly.

Since the structures of the lead frames 82 are identical, only one of the lead frames 82 will be described in the following. Referring to FIGS. 11, 13 and 14, the lead frame 82 includes two spaced-apart sidewalls 821, and a bottom wall 822 connected to bottom portions of the sidewalls 821. The sidewalls 821 and the bottom wall 822 cooperatively define a wire slot 823 thereamong. The wire slot 823 is for disposition of electric wires of the pressure sensor 32 and the temperature sensor 7, so the electric wires are neatly arranged and constrained in the wire slot 823. Each of the sidewalls 821 has a plurality of wire holes 824 (only two is visible in FIG. 14) for extension of the electric wires of the pressure sensor 32 and the temperature sensor 7 so the electric wires may extend outwardly from the wire slot 823.

Referring to FIGS. 9, 10 and 15, the press apparatus (O3) includes the upper die fixture (O2), a lower die fixture 9 that cooperates with the upper die fixture (O2) to press a plurality of the to-be-pressed objects (A0) (only one is shown in FIG. 15) that are the same in number with the press die devices (O1), and a fixture driving member (C0) that is operable to drive the upper die fixture (O2) to move in the axial direction, so that the press die devices (O1) of the upper die fixture (O2) may press the to-be-pressed objects (A0), respectively. The press apparatus (O3) is for pressing each of the to-be-pressed objects (A0) that is an integrated circuit component obtained after placement of a heat sink on a chip in a semiconductor manufacturing process. The lower die fixture 9 has a plurality of lower die seats 91 that are the same in number with the press die devices (O1). Each of the lower die seats 91 is provided for the respective one of the to-be-pressed objects (A0) to be disposed thereon. The fixture driving member (C0) is, for example, but not limited to, a pneumatic cylinder driving member. In the following description, since the structures of the to-be-pressed objects (A0) are identical, the structures the lower die seats 91 are identical, and the structures of the press die devices (O1) are identical, only one of the to-be-pressed objects (A0), the respective one of the lower die seats 91 and the corresponding one of the press die devices (O1) will be described for the sake of brevity.

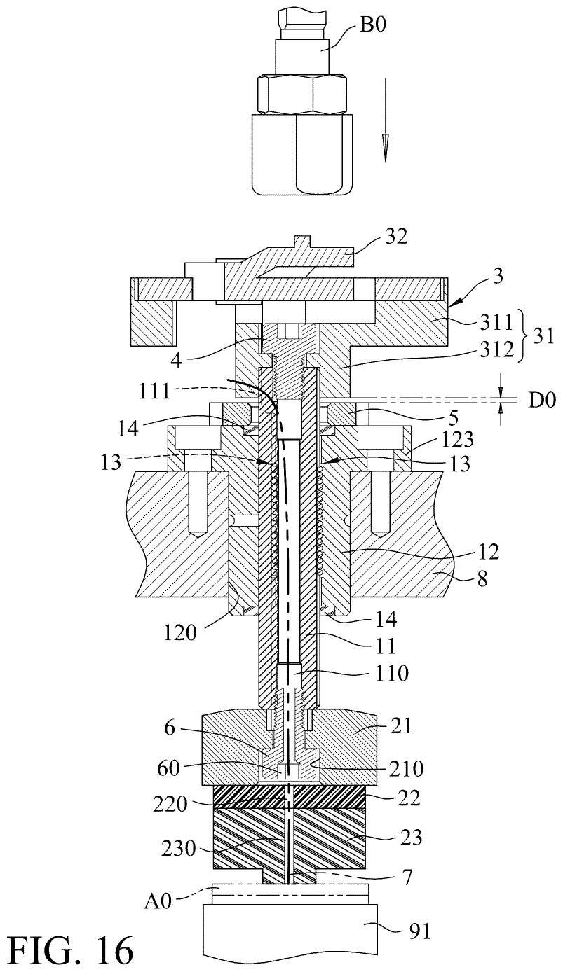

Referring to FIGS. 9, 15 and 16, a procedure of pressing the to-be-pressed object (A0) by the press apparatus (O3) is described in the following. First, the fixture driving member (C0) drives the upper die fixture (O2) to move downwardly toward the lower die fixture 9 in the axial direction until the press die 23 presses against a top surface of the to-be-pressed object (A0). In this embodiment, since the bushing 12 of the connecting assembly 1 of the press die device (O1) is fixedly connected to the upper die seat 8, and the axial rod 11 is movable in the axial direction relative to the bushing 12 and the upper die seat 8, the axial rod 11 drives the press assembly 2 to move therewith downwardly when the upper die fixture (O2) moves downwardly. When the press assembly 2 is moved downwardly, the press die 23 comes into contact with the top surface of the to-be-pressed object (A0) and the axial rod 11 that is fixedly connected to the pressure detection mechanism 3 by the upper fastener 4 moves slightly and upwardly relative to the upper die seat 8 due to a reaction force, creating a gap (D0) (see FIG. 16) between the pressure detection mechanism 3 and the spacer 5. Hereafter, the driving component (B0) presses the pressure detection mechanism 3 downwardly to drive downward movement of the axial rod 11 and to eliminate the gap (D0), then the pressing assembly 2 presses the to-be-pressed object (A0). Thus, packaging of an integrated circuit component is completed after the procedure of pressing the to-be-pressed object (A0) is performed by the press apparatus (O3) of the embodiment of the present disclosure.

It should be noted that, in one embodiment, the upper die fixture (O2) and/or the lower die fixture 9 may include heating modules that heat up the to-be-pressed object (A0) to a predetermined temperature during the procedure of pressing the to-be-pressed object (A0). Since the bottom end of the press die 23 is in contact with the to-be-pressed object (A0) and heat from the to-be-pressed object (A0) is conducted thereto, the temperature sensor 7 extending into the bottom end of the press die 23 may sense a real-time temperature of the to-be-pressed object (A0), and heating power of the heating modules of the upper die fixture (O2) and/or the lower die fixture 9 may be adjusted accordingly.

In summary, in the embodiment of the present disclosure, by virtue of the design of the key connection structures 13 that are disposed between the axial rod 11 and the bushing 12, the axial rod 11 is movable relative to the bushing 12 stably in the axial direction to press the to-be-pressed object (A0) while rotation of the axial rod 11 relative to the bushing 12 is prevented. In this way, the press die device (O1) of the upper die fixture (O2) of the press apparatus (O3) cooperates with the lower die fixture 9 to smoothly and stably press the to-be-pressed object (A0) and is suitable for pressing an integrated circuit component.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in

### The Practice of the Disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A press die device, comprising:
a connecting assembly that includes an axial rod, a bushing sleeved on said axial rod, and at least one key connection structure connecting said axial rod and said bushing; and
a press assembly that is mounted to a bottom end of said axial rod, and that includes a press die adapted to press a to-be-pressed object.

2. The press die device as claimed in claim 1, wherein said at least one key connection structure includes a plurality of key connection structures that are angularly spaced apart from each other.

3. The press die device as claimed in claim 2, wherein:
said bushing is formed with a bushing hole for extension of said axial rod therethrough; and
each of said plurality of key connection structures includes
a key slot formed in an outer peripheral surface of said axial rod and extending in an axial direction of said axial rod,
a connection seat formed in an inner peripheral surface of said bushing that defines said bushing hole and corresponding in position to said key slot, and
a key member interconnecting said key slot and said connection seat, and being a key block that has a rectangular cross-section in the axial direction.

4. The press die device as claimed in claim 2, wherein:
said bushing is formed with a bushing hole for extension of said axial rod therethrough;
each of said plurality of key connection structures includes
a key slot formed in an outer peripheral surface of said axial rod and extending in an axial direction of said axial rod,
a connection seat formed in an inner peripheral surface of said bushing that defines said bushing hole and corresponding in position to said key slot, and
a plurality of key members interconnecting said key slot and said connection seat, and being a plurality of balls freely rotatable in multiple directions.

5. The press die device as claimed in claim 1, wherein:
said bushing is formed with a bushing hole for extension of said axial rod therethrough;
said press assembly is detachably mounted to said bottom end of said axial rod, and further includes a press seat connected to said axial rod, and a heat insulation element mounted to said press seat; and
said press die is mounted to said heat insulation element.

6. The press die device as claimed in claim 5, wherein:
said press die device further comprises a lower fastener;
said axial rod is formed with an axial hole extending in the axial direction; and
said lower fastener connects said press assembly and said axial hole of said axial rod.

7. The press die device as claimed in claim 6, wherein:
said press seat is formed with a lower fastening hole for extension of said lower fastener thereinto;
said lower fastener is formed with a first channel in spatial communication with said axial hole and connecting said press seat and said axial hole of said axial rod;
said heat insulation element is formed with a second channel in spatial communication with said first channel; and
said press die is formed with a third channel in spatial communication with said second channel.

8. The press die device as claimed in claim 7, wherein said bushing hole, said axial hole, said first channel, said second channel, and said third channel extend coaxially.

9. The press die device as claimed in claim 7, wherein:
said press die device further comprises a temperature sensor that extends into said press die through said axial hole, said first channel, said second channel, and said third channel.

10. The press die device as claimed in claim 9, wherein:
an upper portion of said axial rod is formed with a slot in spatial communication with said axial hole; and
said temperature sensor is inserted into said first channel through said slot and said axial hole from an exterior of said axial rod.

11. The press die device as claimed in claim 1, wherein:
said press die device further comprises a pressure detection mechanism mounted on an upper portion of said axial rod.

12. The press die device as claimed in claim 11, wherein:
said pressure detection mechanism includes a support table, and a pressure sensor mounted to an upper portion of said support table.

13. The press die device as claimed in claim 12, wherein:
said support table has a support portion on which said pressure sensor is mounted, and a mount portion sleeved on said axial rod; and
a width of said support portion in a left-right direction transverse to an axial direction of said axial rod is greater than a width of said mount portion in the left-right direction.

14. The press die device as claimed in claim 12, wherein:
said axial rod has a axial hole; and
said press die device further comprises an upper fastener connecting said support table and said the axial hole.

15. The press die device as claimed in claim 12, wherein:
said press die device further comprises a spacer disposed between said support table and said bushing in the axial direction, and formed with an opening for extension of said axial rod therethrough.

16. The press die device as claimed in claim 12, wherein:
said support table has two first side edges transverse to the axial direction, parallel to each other, and perpendicular to a first line;
said bushing has two second side edges transverse to the axial direction, parallel to each other, and perpendicular to a second line; and
a projection of the first line in the axial direction on a horizontal plane that is normal to the axial direction is not parallel to a projection of the second line in the axial direction on the horizontal plane.

17. An upper die fixture, comprising:
at least one press die device as claimed in claim 1; and
an upper die seat that includes at least one mounting area, a number of said at least one mounting area being the same as a number of said at least one press die device, said at least one press die device being mounted to said at least one mounting area;
said at least one press die device being connected to said at least one mounting area by said bushing;
said axial rod being movable in an axial direction of said axial rod and driving said press assembly to move relative to said upper die seat in the axial direction.

18. The upper die fixture as claimed in claim 17, wherein:
said at least one press die device includes a plurality of press die devices;
said at least one mounting area includes a plurality of mounting areas respectively mounted to said plurality of press die devices;
each of said plurality of press die devices further includes a pressure detection mechanism mounted on an upper portion of said axial rod of said connecting assembly of the respective one of said plurality of press die devices, including a support table extending from said bushing of said connecting assembly of the respective one of said plurality of press die devices, and a pressure sensor mounted to an upper portion of said support table; and
said support tables of any two adjacent ones of said plurality of press die devices are arranged staggered in the axial direction.

19. The upper die fixture of claim 18, wherein:
said upper die seat further includes a plurality of lead frames; and
said plurality of press die devices are arranged in at least one row between two adjacent ones of said plurality of lead frames.

20. A press apparatus, comprising:
said upper die fixture as claimed in claim 17, and
a lower die fixture cooperating with said at least one press die device of said upper die fixture to press at least one to-be-pressed object.
